(19) United States
(12) Patent Application Publication
(10) Pub. No.: US 2026/0291178 A1
(43) Pub. Date: Sep. 24, 2026

(54) SEMICONDUCTOR LIGHT-EMITTING ELEMENT

(71) Applicant: SONY GROUP CORPORATION, TOKYO (JP)

(72) Inventors: TAKUMI WATANABE, TOKYO (JP); TOMOHIRO MAKINO, TOKYO (JP); TATSUSHI HAMAGUCHI, TOKYO (JP)

(21) Appl. No.: 19/475,821

(22) PCT Filed: Apr. 4, 2024
(86) PCT No.: PCT/JP2024/013910

§ 371 Date: Oct. 16, 2025

(30) Foreign Application Priority Data
Apr. 25, 2023 (JP) 2023-071762

(51) Int. Cl. H01S 5/06; H01S 5/068; H01S 5/183

(52) U.S. Cl. CPC H01S 5/0612; H01S 5/068; H01S 5/18361

(57) ABSTRACT

Provided is a technique advantageous for stably emitting a desired laser light from a light-emitting unit of a semiconductor light-emitting element even when stress acts on the light-emitting unit.

A semiconductor light-emitting element includes a light-emitting unit including a first distributed Bragg reflector and a second distributed Bragg reflector, and a semiconductor layer and an active layer located between the first distributed Bragg reflector and the second distributed Bragg reflector, and generates laser light, and a stress application unit that applies stress to the light-emitting unit, in which the first distributed Bragg reflector has a laser passing portion through which the laser light emitted from the light-emitting unit passes, and the second distributed Bragg reflector includes a concave reflection portion having a concave shape as viewed from the first distributed Bragg reflector.

### TECHNICAL FIELD

The present disclosure relates to a semiconductor light-emitting element.

### BACKGROUND ART

As a semiconductor light-emitting element that generates laser light, a semiconductor light-emitting element using a distributed Bragg reflector (DBR) is known.

For example, in a DBR type surface emitting laser device disclosed in Patent Document 1, in order to change an oscillation wavelength of laser light, high-frequency vibration is applied to an active layer and members sandwiching the active layer by a vibration member.

### CITATION LIST

### Patent Document

Patent Document 1: Japanese Patent Laid-open Publication No. 2012-9559

### SUMMARY OF THE INVENTION

### Problems to be Solved by the Invention

In a case where stress acts on the active layer of the semiconductor light-emitting element as in the surface emitting laser device disclosed in Patent Document 1, distortion occurs in the semiconductor light-emitting element.

In particular, when stress acts on a semiconductor light-emitting element that generates laser light using a reflector such as a Fabry-Perot semiconductor light-emitting element, the reflector may be distorted. In this case, the laser light is not appropriately reflected by the reflector, the magnitude of output and the emission angle of the laser light unintentionally fluctuate, and the desired laser light may not be stably emitted from the semiconductor light-emitting element.

The present disclosure provides a technique advantageous for stably emitting a desired laser light from a light-emitting unit of a semiconductor light-emitting element even when stress acts on the light-emitting unit.

### Solutions to Problems

One aspect of the present disclosure relates to a semiconductor light-emitting element including a light-emitting unit including a first distributed Bragg reflector and a second distributed Bragg reflector, and a semiconductor layer and an active layer located between the first distributed Bragg reflector and the second distributed Bragg reflector, and generates laser light, and a stress application unit that applies stress to the light-emitting unit, in which the second distributed Bragg reflector includes a concave reflection portion having a concave shape as viewed from the first distributed Bragg reflector.

The light-emitting unit may have a resonator length equal to or less than 50 μm.

The light-emitting unit may have a thickness equal to or less than 60 μm in a stacking direction in which the first distributed Bragg reflector, the active layer, the semiconductor layer, and the second distributed Bragg reflector are arranged.

The stress application unit may be attached to the first distributed Bragg reflector.

The stress application unit may be attached to the second distributed Bragg reflector.

The stress application unit may include a piezoelectric body, and apply a stress corresponding to a voltage applied to the piezoelectric body to the light-emitting unit.

The stress application unit may be energized by an electric circuit independent of an electric circuit for energizing the light-emitting unit.

The light-emitting unit and the stress application unit may be energized by a common electric circuit.

The light-emitting unit may include a first common electrode and a second common electrode to which a common electric circuit is connected, and a connector electrically connected to the first common electrode and the second common electrode, and the connector may include the stress application unit.

The first distributed Bragg reflector may include a laser light transmission portion that allows transmission of the laser light emitted from the light-emitting unit, and
when viewed along an emission direction of the laser light from the light-emitting unit, the laser light transmission portion may be located between the first common electrode and the second common electrode.

The stress application unit may include a MEMS structure.

The MEMS structure may include a first MEMS electrode and a second MEMS electrode, and a stress application layer attached to the light-emitting unit and deformed according to a voltage applied via the first MEMS electrode and the second MEMS electrode, and a stress according to deformation of the stress application layer may be applied to the light-emitting unit.

The first MEMS electrode and the second MEMS electrode may face each other via an air gap interposed therebetween, and the stress application layer may be attached to the first MEMS electrode.

The stress application unit may have a thermal deformation portion having a larger thermal expansion rate than the semiconductor layer.

The thermal expansion rate of the thermal deformation portion may be asymmetric in a stacking direction with reference to a center of the thermal deformation portion in the stacking direction in which the first distributed Bragg reflector, the semiconductor layer, and the second distributed Bragg reflector are arranged.

The stress application unit may include a light deformation portion that deforms according to irradiated light.

The light deformation portion may contain a resin containing azobenzene.

The resin may be a polyimide resin or an epoxy resin.

### BRIEF DESCRIPTION OF DRAWINGS

FIG. 1A is a cross-sectional view illustrating a schematic configuration of an example of a semiconductor light-emitting element.

FIG. 1B is a cross-sectional view illustrating a case where outward force (that is, expansion force) is applied from a stress application unit to a light-emitting unit in the semiconductor light-emitting element illustrated in FIG. 1A.

FIG. 1C is a cross-sectional view illustrating a case where inward force (that is, contraction force) is applied from the stress application unit to the light-emitting unit in the semiconductor light-emitting element illustrated in FIG. 1A.

FIG. 2A is a cross-sectional view illustrating an example of a VCSEL type light-emitting unit, and particularly illustrates a case where a second DBR is configured as a concave DBR.

FIG. 2B is a cross-sectional view illustrating an example of the VCSEL type light-emitting unit, and particularly illustrates a case where the second DBR is configured as a concave DBR.

FIG. 3A is a cross-sectional view illustrating an example of the VCSEL type light-emitting unit, and particularly illustrates a case where the second DBR is configured as a planar DBR.

FIG. 3B is a cross-sectional view illustrating an example of the VCSEL type light-emitting unit, and particularly illustrates a case where the second DBR is configured as a planar DBR.

FIG. 4A is a cross-sectional view illustrating a schematic configuration of an example of a semiconductor light-emitting element of a first embodiment.

FIG. 4B is a cross-sectional view illustrating one form of the semiconductor light-emitting element of the example illustrated in FIG. 4A.

FIG. 4C is a cross-sectional view illustrating another form of the semiconductor light-emitting element of the example illustrated in FIG. 4A.

FIG. 5 is a cross-sectional view illustrating an example in which the semiconductor light-emitting element illustrated in FIG. 4B is applied to the VCSEL type light-emitting unit.

FIG. 6 is a cross-sectional view illustrating another example in which the semiconductor light-emitting element illustrated in FIG. 4B is applied to the VCSEL type light-emitting unit.

FIG. 7A illustrates an example in which the semiconductor light-emitting element illustrated in FIG. 4C is applied to the VCSEL type light-emitting unit, and is a top view of the semiconductor light-emitting element.

FIG. 7B illustrates an example in which the semiconductor light-emitting element illustrated in FIG. 4C is applied to the VCSEL type light-emitting unit, and is a cross-sectional view of the semiconductor light-emitting element.

FIG. 8 is a cross-sectional view illustrating a schematic configuration of an example of a semiconductor light-emitting element of a second embodiment.

FIG. 9A is a cross-sectional view illustrating an example in which the semiconductor light-emitting element illustrated in FIG. 8 is applied to the VCSEL type light-emitting unit.

FIG. 9B is a cross-sectional view illustrating an example in which the semiconductor light-emitting element illustrated in FIG. 8 is applied to the VCSEL type light-emitting unit.

FIG. 10A is a cross-sectional view illustrating another example in which the semiconductor light-emitting element illustrated in FIG. 8 is applied to the VCSEL type light-emitting unit.

FIG. 10B is a cross-sectional view illustrating another example in which the semiconductor light-emitting element illustrated in FIG. 8 is applied to the VCSEL type light-emitting unit.

FIG. 11 is a cross-sectional view illustrating a schematic configuration of an example of a semiconductor light-emitting element of a third embodiment.

FIG. 12A is a cross-sectional view illustrating an example in which the semiconductor light-emitting element illustrated in FIG. 11 is applied to the VCSEL type light-emitting unit.

FIG. 12B is a cross-sectional view illustrating another example in which the semiconductor light-emitting element illustrated in FIG. 11 is applied to the VCSEL type light-emitting unit.

FIG. 13A is a cross-sectional view illustrating a schematic configuration of another example of the semiconductor light-emitting element of the third embodiment.

FIG. 13B is a cross-sectional view illustrating a schematic configuration of another example of the semiconductor light-emitting element of the third embodiment.

FIG. 14 is a view illustrating an example of a relationship between a thickness position in a stacking direction of a stress application unit and a thermal expansion rate.

FIG. 15 is a cross-sectional view illustrating an example in which the semiconductor light-emitting element illustrated in FIG. 13A is applied to the VCSEL type light-emitting unit.

FIG. 16 is a cross-sectional view illustrating another example in which the semiconductor light-emitting element illustrated in FIG. 13A is applied to the VCSEL type light-emitting unit.

FIG. 17 is a cross-sectional view illustrating another example in which the semiconductor light-emitting element illustrated in FIG. 13A is applied to the VCSEL type light-emitting unit.

FIG. 18 is a cross-sectional view illustrating another example in which the semiconductor light-emitting element illustrated in FIG. 13A is applied to the VCSEL type light-emitting unit.

FIG. 19 is a cross-sectional view illustrating a schematic configuration of an example of a semiconductor light-emitting element of a fourth embodiment.

FIG. 20 is a view for describing a photoisomerization reaction of azobenzene.

FIG. 21 is a chemical formula illustrating an example of a resin that can constitute the light deformation portion, and particularly illustrates an example of a resin having an azobenzene skeleton.

FIG. 22 is a cross-sectional view illustrating an example in which the semiconductor light-emitting element illustrated in FIG. 19 is applied to the VCSEL type light-emitting unit.

FIG. 23 is a cross-sectional view illustrating another example in which the semiconductor light-emitting element illustrated in FIG. 19 is applied to the VCSEL type light-emitting unit.

### MODE FOR CARRYING OUT THE INVENTION

Hereinafter, embodiments of the present disclosure will be exemplarily illustrated with reference to the drawings.

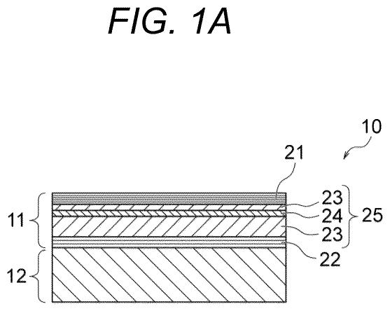

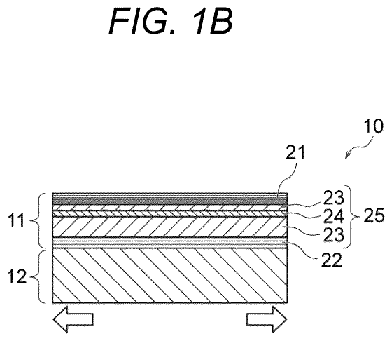

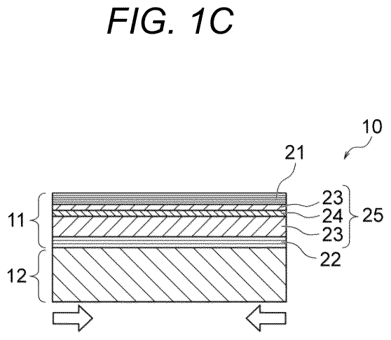

FIG. 1A is a cross-sectional view illustrating a schematic configuration of an example of a semiconductor light-emitting element 10. FIG. 1B is a cross-sectional view illustrating a case where outward force (that is, expansion force) is applied from a stress application unit 12 to a light-emitting unit 11 in the semiconductor light-emitting element 10 illustrated in FIG. 1A. FIG. 1C is a cross-sectional view illustrating a case where inward force (that is, contraction force) is applied from the stress application unit 12 to the light-emitting unit 11 in the semiconductor light-emitting element 10 illustrated in FIG. 1A.

The semiconductor light-emitting element 10 illustrated in FIG. 1A includes the light-emitting unit 11 that generates laser light, and the stress application unit 12 that applies stress to the light-emitting unit 11.

The light-emitting unit 11 includes a first DBR 21 and a second DBR 22, and a semiconductor layer 23 and an active layer 24 located between the first DBR 21 and the second DBR 22. The active layer 24 is sandwiched between the semiconductor layers 23, and the active layer 24 and the semiconductor layers 23 constitute a stacked structure 25.

When energy is supplied, the stress application unit 12 exhibits a larger dimensional change than the stacked structure 25 (that is, the semiconductor layer 23 and the active layer 24) of the light-emitting unit 11, and as a result, stress is applied to the active layer 24.

The form of the energy supplied to the stress application unit 12 is not limited. For example, when electric energy, thermal energy, or light energy as described later is applied to the stress application unit 12, the stress application unit 12 may apply stress to the light-emitting unit 11 (particularly, the active layer 24).

The polarization state of the laser light oscillated in the light-emitting unit 11 changes according to the stress applied to the active layer 24. Therefore, by controlling the stress applied to the light-emitting unit 11 by the stress application unit 12, the polarization state of the laser light oscillated by the light-emitting unit 11 can be dynamically controlled. For example, as illustrated in FIG. 1B, by intentionally expanding and deforming the stress application unit 12 by controlling the energy supplied to the stress application unit 12, it is possible to apply stress acting in an expansion direction to the active layer 24 of the light-emitting unit 11 attached to the stress application unit 12. On the other hand, as illustrated in FIG. 1C, by controlling the energy supplied to the stress application unit 12 to intentionally shrink and deform the stress application unit 12, it is possible to apply a stress acting in a contraction direction to the active layer 24 of the light-emitting unit 11 attached to the stress application unit 12.

By actively controlling the energy supplied to the stress application unit 12 in this manner, the polarization state of the laser light emitted from the light-emitting unit 11 can be dynamically changed to a desired state without greatly changing the output or emission angle of the laser light. Note that the technology of the present disclosure is applicable not only to a case where the energy supplied to the stress application unit 12 is actively controlled, but also to a case where the energy supplied to the stress application unit 12 is not actively controlled.

In the example illustrated in FIGS. 1A to 1C, the stress application unit 12 separate from the light-emitting unit 11 is attached to the light-emitting unit 11, but the stress application unit 12 may be provided inside the light-emitting unit 11. That is, a part of the elements constituting the light-emitting unit 11 may be provided as the stress application unit 12. Also in this case, by applying energy to some elements of the light-emitting unit 11 provided as the stress application unit 12, stress can be applied to the active layer 24 of the light-emitting unit 11.

Next, an example in which the light-emitting unit 11 of the semiconductor light-emitting element 10 is configured as a vertical cavity surface emitting laser (VCSEL) will be described.

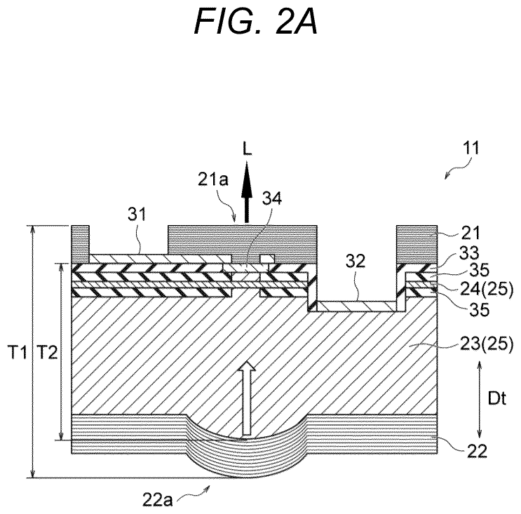

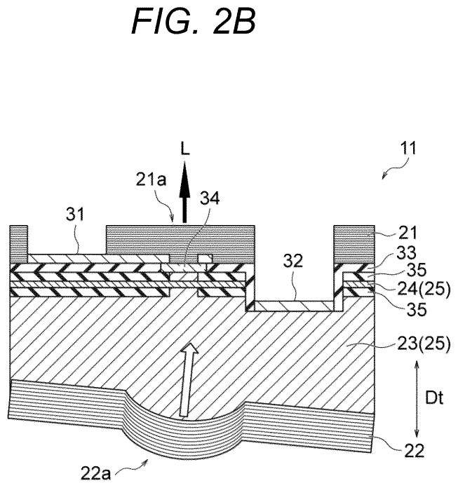

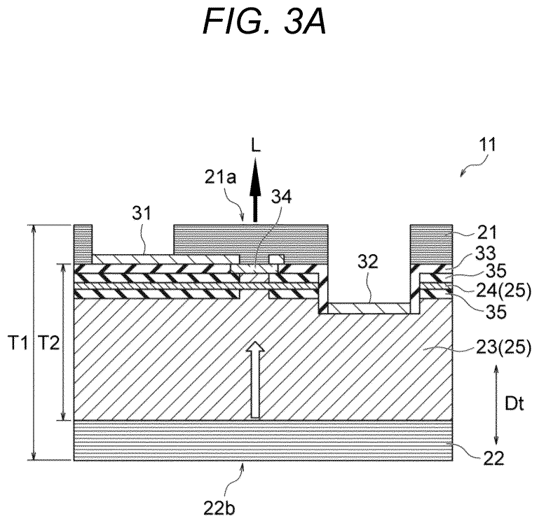

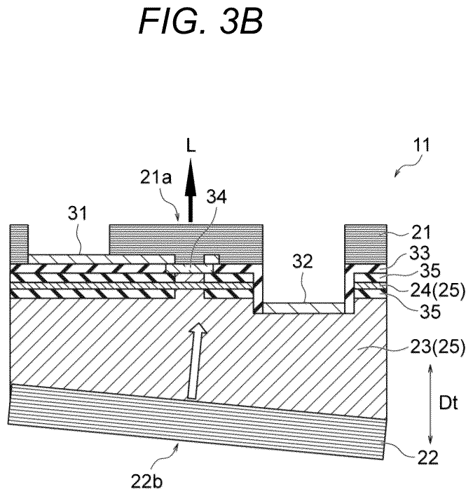

FIGS. 2A and 2B are cross-sectional views illustrating an example of the VCSEL type light-emitting unit 11, and particularly illustrate a case where the second DBR 22 is configured as a concave DBR. FIGS. 3A and 3B are cross-sectional views illustrating an example of the VCSEL type light-emitting unit 11, and particularly illustrate a case where the second DBR 22 is configured as a planar DBR. FIGS. 2A and 3A illustrate a state in which no stress is applied to the stacked structure 25, and FIGS. 2B and 3B illustrate a state in which stress is applied to the stacked structure 25.

The light-emitting units 11 illustrated in FIGS. 2A to 3B have the same configuration except for the second DBR 22 (particularly, the shape of the light reflection surface). That is, the light-emitting unit 11 includes a p-type semiconductor layer electrode 31, an n-type semiconductor layer electrode 32, an insulating layer 33, a transparent conductive film 34, and a high electric resistance region 35 in addition to the first DBR 21, the second DBR 22, and the stacked structure 25 (that is, the semiconductor layer 23 and the active layer 24) described above.

The p-type semiconductor layer electrode 31 and the n-type semiconductor layer electrode 32 are connected to an electric circuit as a drive source of the light-emitting unit 11, and are provided as electrodes for injecting a current for laser light oscillation into the stacked structure 25 (particularly, the active layer 24). The p-type semiconductor layer electrode 31 and the n-type semiconductor layer electrode 32 can be formed by any conductive material, and are typically formed by metal.

The p-type semiconductor layer electrode 31 is provided so as to cover only a partial range of the semiconductor layer 23 and the active layer 24, and is electrically connected to the p-type semiconductor layer of the light-emitting unit 11. A part of the p-type semiconductor layer electrode 31 is exposed to the outside through a through hole of the first DBR 21, and an electric circuit is connected to the exposed part. The other part of the p-type semiconductor layer electrode 31 is covered with the first DBR 21 and is not exposed to the outside.

The p-type semiconductor layer electrode 31 has a through hole in which the first DBR 21 (particularly, a laser light transmission portion 21a to be described later) exists. The laser light L is emitted from the light-emitting unit 11 through the through hole (in a strict sense, the first DBR 21 (laser light transmission portion 21a) in the through hole) of the p-type semiconductor layer electrode 31.

The n-type semiconductor layer electrode 32 is provided so as to cover only a partial range of the semiconductor layer 23 and the active layer 24, and is connected to the n-type semiconductor layer of the light-emitting unit 11. The n-type semiconductor layer electrode 32 is exposed to the outside through a through hole of the first DBR 21, and an electric circuit is connected to the exposed portion. The n-type semiconductor layer electrode 32 is in contact with the semiconductor layer 23 (particularly, the semiconductor layer 23 located between the active layer 24 and the second DBR 22), and is surrounded by the insulating layer 33.

The insulating layer 33 is constituted by a non-conductor (for example, SiO2) which hardly allows electricity to pass therethrough. The insulating layer 33 has a through hole in which the n-type semiconductor layer electrode 32 is disposed and a through hole in which the transparent conductive film 34 is disposed. In a stacking direction Dt, the first DBR 21 and the p-type semiconductor layer electrode 31 are provided on one side (upper side in FIGS. 2A to 3B) of the insulating layer 33, and the high electric resistance region 35, the stacked structure 25, and the second DBR 22 are provided on the other side (lower side in FIGS. 2A to 3B) of the insulating layer 33.

The stacking direction Dt mentioned here means a direction in which the first DBR 21, the semiconductor layer 23, the active layer 24, and the second DBR 22 are arranged (vertical direction in FIGS. 2A to 3B). In the present example, the stacking direction Dt coincides with a reflection direction of the laser light between the first DBR 21 and the second DBR 22, and also coincides with the emission direction of the laser light L from the light-emitting unit 11.

The transparent conductive film 34 is formed by any material (for example, indium tin oxide (ITO)) that can transmit visible light (particularly, the laser light L emitted from the light-emitting unit 11) and has conductivity. The transparent conductive film 34 is provided so as to be in contact with the p-type semiconductor layer electrode 31 and the semiconductor layer 23 (particularly, the semiconductor layer 23 located between the first DBR 21 and the active layer 24), and ensures the flow of current between the p-type semiconductor layer electrode 31 and the semiconductor layer 23.

The high electric resistance region 35 is a region that has a higher electric resistance than the adjacent semiconductor layer 23 and active layer 24, and is a region where electricity flows less easily than in the semiconductor layer 23 and the active layer 24.

The high electric resistance region 35 can have any configuration, and can be configured by, for example, an ion implantation region in which ions (for example, boron (B)) are implanted into the semiconductor layer 23.

The high electric resistance region 35 is provided so as to partially cover the semiconductor layer 23. That is, the high electric resistance region 35 is provided so as not to cover a portion of the semiconductor layer 23 and a portion of the active layer 24 (particularly, a portion facing at least a portion of the transparent conductive film 34 in the stacking direction Dt). Thus, a contact state of the semiconductor layer 23 with the transparent conductive film 34 is secured, and a flow of a current between the transparent conductive film 34 and the semiconductor layer 23 (eventually, the active layer 24) is secured.

The first DBR 21, the second DBR 22, the semiconductor layer 23, and the active layer 24 can also be formed by any material. As an example, the first DBR 21 and the second DBR 22 can be configured by a Ti2O5/SiO2 multilayer film, and the semiconductor layer 23 can be configured by a semiconductor material such as gallium nitride (GaN).

The light-emitting unit 11 having the above-described configuration has a portion where the p-type semiconductor layer electrode 31, the insulating layer 33, the high electric resistance region 35, the active layer 24, and the high electric resistance region 35 are sequentially stacked in the stacking direction Dt between the first DBR 21 and the semiconductor layer 23. Furthermore, the light-emitting unit 11 has a portion where the insulating layer 33, the high electric resistance region 35, the active layer 24, and the high electric resistance region 35 are sequentially stacked in the stacking direction Dt between the first DBR 21 and the semiconductor layer 23.

The first DBR 21 includes the laser light transmission portion 21a that allows transmission of the laser light L (that is, the laser light L having a desired specific wavelength) emitted from the light-emitting unit 11.

In the light-emitting unit 11 illustrated in FIGS. 2A and 2B, the second DBR 22 has a concave reflection portion 22a having a concave shape as viewed from the first DBR 21. A normal direction of at least a part of the concave reflection portion 22a (particularly, a reflection surface that is in contact with the semiconductor layer 23 and forms a boundary surface) is directed to the laser light transmission portion 21a of the first DBR 21.

The laser light transmission portion 21a, the through hole of the p-type semiconductor layer electrode 31, the transparent conductive film 34, portions of the semiconductor layer 23 and the active layer 24 not covered with the high electric resistance region 35, and the concave reflection portion 22a are arranged on the same straight line extending in the stacking direction Dt, and constitute a waveguide of the laser light L.

The configuration of the second DBR 22 as a concave DBR as illustrated in FIGS. 2A and 2B is advantageous for ensuring appropriate light reflection characteristics under a situation where distortion may occur in the light-emitting unit 11 (for example, the stacked structure 25).

That is, as illustrated in FIG. 2B, when stress is applied to the stacked structure 25 (the semiconductor layer 23 and the active layer 24) and the stacked structure is distorted, the second DBR 22 is similarly distorted, but the concave reflection portion 22a is likely to maintain the state of being directed to the laser light transmission portion 21a of the first DBR 21. Therefore, even when the stacked structure 25 is distorted, the concave reflection portion 22a functions to stably propagate the laser light back and forth along the waveguide between the first DBR 21 and the second DBR 22, and effectively focuses the laser light on the portion of the active layer 24 not covered by the high electric resistance region 35.

Even in a state where distortion occurs in the stacked structure 25 and the second DBR 22 as described above, the laser light is appropriately and repeatedly reflected by the first DBR 21 and the second DBR 22, and the laser light L having a desired wavelength is emitted from the light-emitting unit 11.

On the other hand, in the example illustrated in FIGS. 3A and 3B, the second DBR 22 has a flat shape when viewed from the first DBR 21, and a reflection surface (flat reflecting portion 22b) of the second DBR 22 extends flat. Thus, as illustrated in FIG. 3B, the direction of the reflection surface of the second DBR 22 changes according to the distortion generated in the stacked structure 25 and the second DBR 22. In this case, the laser light is likely to be directed to a portion of the first DBR 21 away from the laser light transmission portion 21a by reflection on the reflection surface of the second DBR 22.

In a case where the semiconductor light-emitting element 10 includes the second DBR 22 (see FIGS. 3A and 3B) configured as a planar DBR in this manner, when the stacked structure 25 and the second DBR 22 are distorted by stress, the output and the emission angle of the laser light L from the light-emitting unit 11 are likely to unintentionally fluctuate. Therefore, configuring the second DBR 22 as a planar DBR is disadvantageous in ensuring appropriate light reflection characteristics under a situation where distortion may occur in the light-emitting unit 11 (for example, the stacked structure 25).

Note that the emission characteristics of the laser light L from the light-emitting unit 11 tend to be more affected by the stress applied to the stacked structure 25 as the thickness of the light-emitting unit 11 (that is, the size in the stacking direction Dt) is smaller.

For example, in a case where the light-emitting unit 11 has the stacking direction thickness T1 (that is, the chip thickness and the element thickness) equal to or less than 60 um with respect to the stacking direction Dt, it is easy to enjoy the benefit of the stable emission characteristic of the laser light L provided by the concave reflection portion 22a more effectively. Furthermore, in a case where the light-emitting unit 11 has the resonator length T2 equal to or less than 50 μm, it is easy to enjoy the benefit of the stable emission characteristic of the laser light L provided by the concave reflection portion 22a.

The stacking direction thickness T1 mentioned herein is the length of the portion having the largest size of the light-emitting unit 11 in the stacking direction Dt. In the light-emitting unit 11 illustrated in FIGS. 2A to 3B, the distance in the stacking direction Dt between the outermost surface (upper surface) of the first DBR 21 and the outermost surface (the outermost surface (lower surface) of the concave reflection portion 22a in the example illustrated in FIGS. 2A and 2B) of the second DBR 22 is the stacking direction thickness T1.

On the other hand, the resonator length T2 is a distance between light reflecting portions in the light-emitting unit 11. In the light-emitting unit 11 illustrated in FIGS. 2A to 3B, the distance in the stacking direction Dt between the surface (lower surface) of the first DBR 21 on the stacked structure 25 side and the surface (upper surface) of the second DBR 22 (the concave reflection portion 22a in the example illustrated in FIGS. 2A and 2B) on the stacked structure 25 side is the resonator length T2.

Note that the dimensional change of the semiconductor light-emitting element 10 caused by the stress applied to the light-emitting unit 11 by the stress application unit 12 can be measured by any method. For example, the dimensional change of the semiconductor light-emitting element 10 may be measured in a state where a part of the semiconductor light-emitting element 10 is removed by a physical polishing treatment or a chemical etching treatment. In addition, regarding both the state in which energy is supplied to the stress application unit 12 and the state in which energy is not supplied to the stress application unit 12, an image of the semiconductor light-emitting element 10 may be acquired by performing imaging, and a dimensional change of the semiconductor light-emitting element 10 may be derived by analyzing these images.

Next, a more specific embodiment of the semiconductor light-emitting element 10 will be described.

### First Embodiment

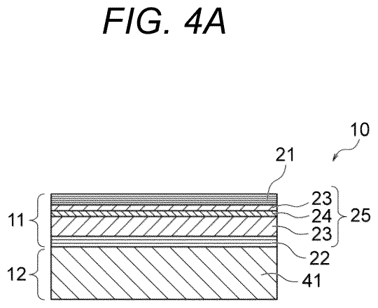

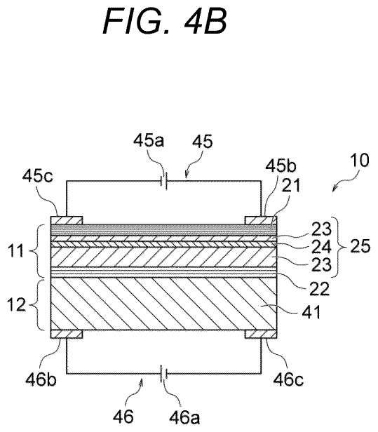

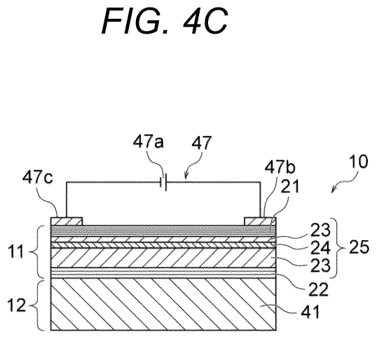

FIG. 4A is a cross-sectional view illustrating a schematic configuration of an example of the semiconductor light-emitting element 10 of the first embodiment.

The semiconductor light-emitting element 10 illustrated in FIG. 4A has a configuration similar to that of the semiconductor light-emitting element 10 illustrated in FIG. 1A described above, but the stress application unit 12 includes a piezoelectric body 41 exhibiting a piezoelectric effect. The piezoelectric body 41 applies stress corresponding to an applied voltage to the light-emitting unit 11.

The piezoelectric body 41 can be formed by any piezoelectric material that exhibits a dimensional change according to an applied voltage. For example, the piezoelectric body 41 may contain an inorganic material such as Si02 and lead zirconate titanate (PZT) or an organic material such as polylactic acid (PLA) and polyvinylidene fluoride (PVDF). These piezoelectric materials are relatively inexpensive, and can be suitably used as a constituent material of the piezoelectric body 41 (stress application unit 12) having a desired thickness.

The electric energy supplied to the piezoelectric body 41 may be supplied to the piezoelectric body 41 from an electric circuit different from the electric circuit that supplies the electric energy to the light-emitting unit 11, or may be supplied to the piezoelectric body 41 from the same electric circuit.

FIG. 4B is a cross-sectional view illustrating one form of the semiconductor light-emitting element 10 of the example illustrated in FIG. 4A.

The semiconductor light-emitting element 10 illustrated in FIG. 4B includes a light emission electric circuit 45 and a stress application electric circuit 46 provided as electric circuits separate from each other. The light emission electric circuit 45 is an electric circuit for supplying electric energy to the light-emitting unit 11 for oscillation of laser light. The stress application electric circuit 46 is an electric circuit for supplying electric energy to the piezoelectric body 41 of the stress application unit 12.

The light-emitting unit 11 is electrically connected to the electrodes 45b and 45c of the light emission electric circuit 45, and is supplied with a current from the power supply 45a. The piezoelectric body 41 of the stress application unit 12 is electrically connected to the electrodes 46b and 46c of the stress application electric circuit 46, and a current is supplied from the power supply 46a.

As described above, the stress application unit 12 may be energized by the stress application electric circuit 46 independent of the light emission electric circuit 45 for energizing the light-emitting unit 11 (particularly, the active layer 24).

FIG. 4C is a cross-sectional view illustrating another form of the semiconductor light-emitting element 10 of the example illustrated in FIG. 4A.

The semiconductor light-emitting element 10 illustrated in FIG. 4C includes a common electric circuit 47 provided as an electric circuit shared by the light-emitting unit 11 and the stress application unit 12. That is, the common electric circuit 47 is an electric circuit for supplying electric energy to the light-emitting unit 11 for oscillation of laser light, and is also an electric circuit for supplying electric energy to the piezoelectric body 41 of the stress application unit 12.

The common electric circuit 47 illustrated in FIG. 4C includes electrodes 47b and 47c electrically connected to both the light-emitting unit 11 and the stress application unit 12, and the current from the power supply 47a is supplied to both the light-emitting unit 11 and the stress application unit 12 via the electrodes 47b and 47c.

In this manner, the light-emitting unit 11 and the stress application unit 12 may be energized by the common electric circuit 47.

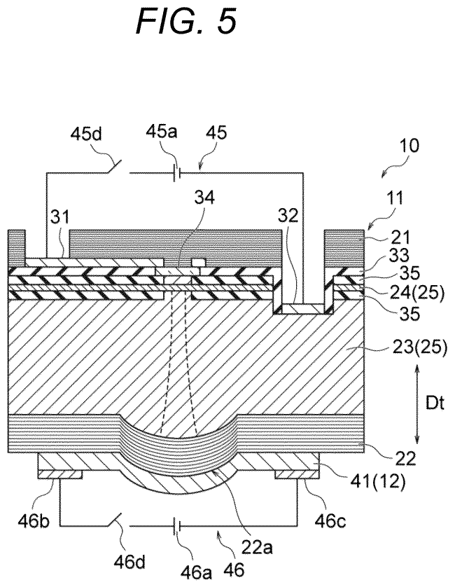

FIG. 5 is a cross-sectional view illustrating an example in which the semiconductor light-emitting element 10 illustrated in FIG. 4B is applied to a VCSEL type light-emitting unit 11.

In the semiconductor light-emitting element 10 illustrated in FIG. 5, the light-emitting unit 11 has the same structure as the light-emitting unit 11 illustrated in FIG. 2A described above, and the stress application unit 12 is attached to the second DBR 22 of the light-emitting unit 11. That is, the piezoelectric body 41 of the stress application unit 12 is installed on a surface (that is, a surface constituted by the second DBR 22) opposite to the emission surface of the laser light constituted by the first DBR 21.

The light emission electric circuit 45 is connected to the p-type semiconductor layer electrode 31 and the n-type semiconductor layer electrode 32 of the light-emitting unit 11, and a current from the power supply 45a of the light emission electric circuit 45 is supplied to the semiconductor layer 23 and the active layer 24 via the p-type semiconductor layer electrode 31 and the n-type semiconductor layer electrode 32.

The power supply 46a of the stress application electric circuit 46 is electrically connected to the piezoelectric body 41 (stress application unit 12) via the electrodes 46b and 46c, and a current from the power supply 46a is supplied to the piezoelectric body 41 via the electrodes 46b and 46c.

As described above, in the semiconductor light-emitting element 10 illustrated in FIG. 5, the stress application electric circuit 46 independent of the light emission electric circuit 45 for injecting a current into the active layer 24 of the VCSEL type light-emitting unit 11 is provided for the piezoelectric body 41 (stress application unit 12). Note that the light emission electric circuit 45 illustrated in FIG. 5 has a switch 45d that can be switched on and off, and the stress application electric circuit 46 has a switch 46d that can be switched on and off.

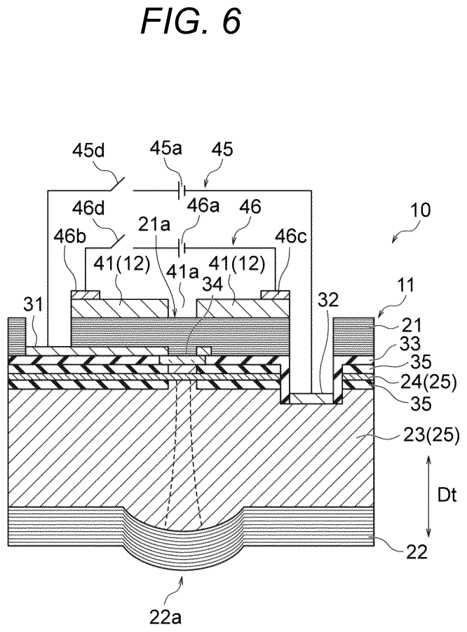

FIG. 6 is a cross-sectional view illustrating another example in which the semiconductor light-emitting element 10 illustrated in FIG. 4B is applied to the VCSEL type light-emitting unit 11.

In the semiconductor light-emitting element 10 illustrated in FIG. 6, the light-emitting unit 11 has the same structure as the light-emitting unit 11 illustrated in FIG. 2A described above, and the stress application unit 12 (piezoelectric body 41) is attached to the first DBR 21 of the light-emitting unit 11. That is, the piezoelectric body 41 of the stress application unit 12 is installed on the emission surface of the laser light (that is, the surface constituted by the first DBR 21).

The piezoelectric body 41 has a through hole constituting the laser light passing portion 41a. The laser light passing portion 41a of the piezoelectric body 41 faces the laser light transmission portion 21a of the first DBR 21 in the stacking direction Dt. That is, the laser light passing portion 41a, the laser light transmission portion 21a, the through hole of the p-type semiconductor layer electrode 31, the transparent conductive film 34, the portions of the semiconductor layer 23 and the active layer 24 not covered with the high electric resistance region 35, and the concave reflection portion 22a are arranged on the same straight line extending in the stacking direction Dt, and constitute a waveguide of the laser light L.

As described above, since the piezoelectric body 41 has the laser light passing portion 41a, even if the stress application unit 12 (piezoelectric body 41) is provided on the emission surface of the laser light, the laser light can be appropriately emitted from the light-emitting unit 11. Note that, in the example illustrated in FIG. 6, the laser light passing portion 41a is constituted by the through hole, but a part or all of the laser light passing portion 41a may be constituted by a tangible object through which the laser light can pass.

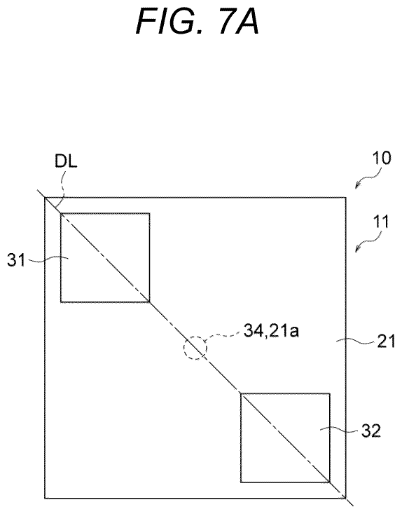

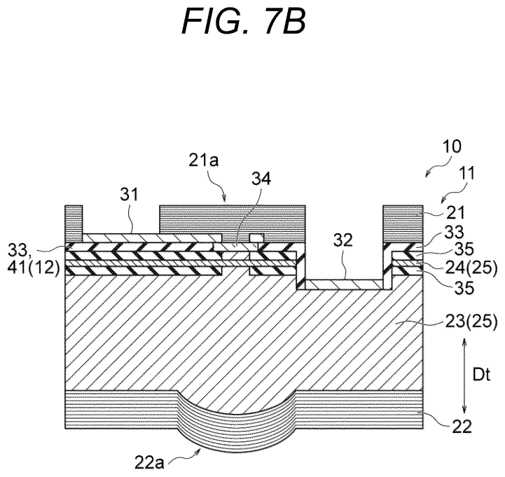

FIGS. 7A and 7B illustrate an example in which the semiconductor light-emitting element 10 illustrated in FIG. 4C is applied to the VCSEL type light-emitting unit 11, FIG. 7A is a top view of the semiconductor light-emitting element 10, and FIG. 7B is a cross-sectional view of the semiconductor light-emitting element 10.

In the semiconductor light-emitting element 10 of the present example, the insulating layer 33 of the light-emitting unit 11 includes the piezoelectric body 41 and serves as the stress application unit 12.

That is, to the p-type semiconductor layer electrode 31 (first common electrode) and the n-type semiconductor layer electrode 32 (second common electrode) of the light-emitting unit 11, a common electric circuit 47 is connected (not illustrated in FIGS. 7A and 7B; see FIG. 4C). Then, the insulating layer 33, which is a “connector electrically connected to the p-type semiconductor layer electrode 31 and the n-type semiconductor layer electrode 32”, includes the piezoelectric body 41 of the stress application unit 12.

The p-type semiconductor layer electrode 31 is connected to the transparent conductive film 34 and the piezoelectric body 41 included in the insulating layer 33. Therefore, the p-type semiconductor layer electrode 31 and the n-type semiconductor layer electrode 32 are electrically conducted to each other via the transparent conductive film 34, the semiconductor layer 23, and the active layer 24, and are electrically conducted to each other via the piezoelectric body 41 included in the insulating layer 33.

As described above, the common electric circuit 47 is shared by the piezoelectric body 41 (stress application unit 12) and the active layer 24 (light-emitting unit 11).

Note that, as illustrated in FIG. 7A, the p-type semiconductor layer electrode 31 and the n-type semiconductor layer electrode 32 of the present example are located on a diagonal line DL of a quadrangular (square) planar shape of the light-emitting unit 11 with the transparent conductive film 34 and the laser light transmission portion 21a interposed therebetween. As described above, when viewed along the emission direction of the laser light from the light-emitting unit 11, the waveguide of the laser light in the light-emitting unit 11 is located between the p-type semiconductor layer electrode 31 (first common electrode) and the n-type semiconductor layer electrode 32 (second common electrode), so that stress can be efficiently applied to the active layer 24.

### Second Embodiment

In the present embodiment, elements same as or corresponding to those in the first embodiment described above will be denoted by the same reference signs, and detailed descriptions thereof will be omitted.

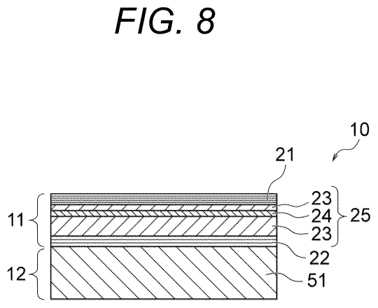

FIG. 8 is a cross-sectional view illustrating a schematic configuration of an example of a semiconductor light-emitting element 10 of the second embodiment.

The semiconductor light-emitting element 10 illustrated in FIG. 8 has a configuration similar to that of the semiconductor light-emitting element 10 illustrated in FIG. 1A described above, but the stress application unit 12 includes a MEMS structure 51.

The MEMS structure 51 is a micro electro mechanical system (MEMS) having any structure. The form of energy supplied from a drive source to the MEMS structure 51 for driving the MEMS structure 51 is also not limited, and the MEMS structure 51 may be configured by, for example, an electrostatic MEMS using electrostatic force.

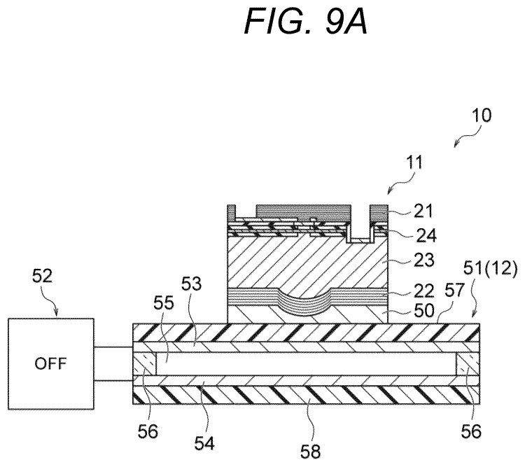

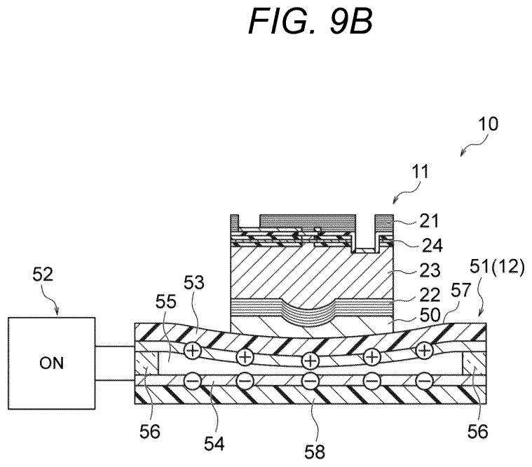

FIGS. 9A and 9B are cross-sectional views illustrating an example in which the semiconductor light-emitting element 10 illustrated in FIG. 8 is applied to the VCSEL type light-emitting unit 11. FIG. 9A illustrates an example of a state in which the MEMS electric circuit 52 that supplies power to the MEMS structure 51 is off, and FIG. 9B illustrates an example of a state in which the MEMS electric circuit 52 that supplies power to the MEMS structure 51 is on.

In the semiconductor light-emitting element 10 illustrated in FIGS. 9A and 9B, the light-emitting unit 11 has the same structure as the light-emitting unit 11 illustrated in FIG. 2A described above, and the stress application unit 12 is attached to the light-emitting unit 11. That is, the MEMS structure 51 of the stress application unit 12 is installed on a surface (that is, a surface constituted by the second DBR 22) opposite to the emission surface of the laser light constituted by the first DBR 21.

Also in the present example, the light emission electric circuit 45 (not illustrated in FIGS. 9A and 9B; see FIG. 4B) is connected to the p-type semiconductor layer electrode 31 and the n-type semiconductor layer electrode 32 of the light-emitting unit 11. Furthermore, the MEMS electric circuit 52 provided as an electric circuit separate from the light emission electric circuit 45 is electrically connected to the MEMS structure 51 (particularly, a first MEMS electrode 53 and a second MEMS electrode 54).

The MEMS structure 51 includes the first MEMS electrode 53, the second MEMS electrode 54, and a mounting substrate 57 serving as a stress application layer.

The first MEMS electrode 53 and the second MEMS electrode 54 are attached to each other with a spacer 56 having an electrical insulation property interposed therebetween, and face each other with an air gap 55 interposed therebetween.

The first MEMS electrode 53 is attached to the mounting substrate 57, and is deformed according to a voltage applied to the first MEMS electrode 53 and the second MEMS electrode 54. The mounting substrate 57 is attached to the first MEMS electrode 53, is attached to the light-emitting unit 11 (particularly, the second DBR 22) via a connection layer 50, and is deformed together with first MEMS electrode 53. As a result, stress corresponding to deformation of the first MEMS electrode 53 and the mounting substrate 57 is applied to the light-emitting unit 11.

The second MEMS electrode 54 is attached to a support substrate 58 having flexural rigidity higher than that of the mounting substrate 57, and maintains a flat plate shape while being supported by the support substrate 58.

In the present example, when the MEMS electric circuit 52 is turned on, the first MEMS electrode 53 is positively charged and the second MEMS electrode 54 is negatively charged as illustrated in FIG. 9B. As a result, electrostatic force (particularly attractive force) acts on the first MEMS electrode 53 and the second MEMS electrode 54, the first MEMS electrode 53 is convexly curved toward the second MEMS electrode 54, and stress is applied to the light-emitting unit 11 (particularly the active layer 24).

As described above, in the semiconductor light-emitting element 10 of the present example, the MEMS electric circuit 52 independent of the light emission electric circuit 45 (not illustrated in FIGS. 9A and 9B) for injecting a current into the active layer 24 of the light-emitting unit 11 is provided for driving the MEMS structure 51 (stress application unit 12).

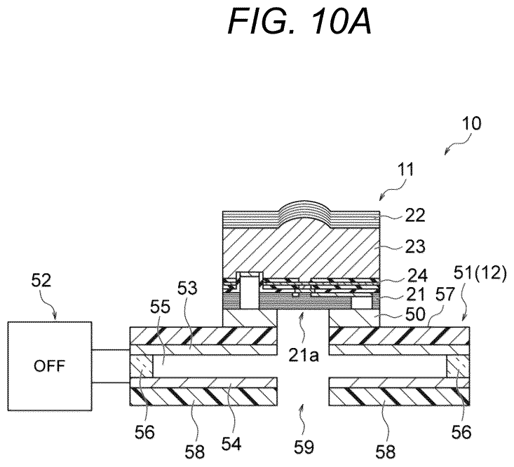

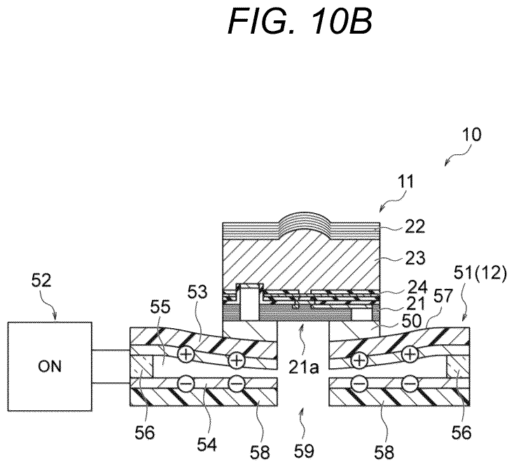

FIGS. 10A and 10B are cross-sectional views illustrating another example in which the semiconductor light-emitting element 10 illustrated in FIG. 8 is applied to the VCSEL type light-emitting unit 11.

In the semiconductor light-emitting element 10 illustrated in FIGS. 10A and 10B, the light-emitting unit 11 has the same structure as the light-emitting unit 11 illustrated in FIG. 2A described above, and the stress application unit 12 is attached to the light-emitting unit 11 (particularly, the first DBR 21). That is, the MEMS structure 51 of the stress application unit 12 is installed on the emission surface of the laser light (that is, the surface configured by the first DBR 21) via the connection layer 50.

The MEMS structure 51 has a through hole constituting the laser light passing portion 59. The laser light passing portion 59 of the MEMS structure 51 faces the laser light transmission portion 21a of the first DBR 21 in the stacking direction Dt. That is, the laser light passing portion 59, the laser light transmission portion 21a, the through hole of the p-type semiconductor layer electrode 31, the transparent conductive film 34, the portions of the semiconductor layer 23 and the active layer 24 not covered with the high electric resistance region 35, and the concave reflection portion 22a are arranged on the same straight line extending in the stacking direction Dt, and constitute a waveguide of the laser light L.

Since the MEMS structure 51 includes the laser light passing portion 59 as described above, the laser light can be appropriately emitted from the light-emitting unit 11 even if the stress application unit 12 (MEMS structure 51) is provided on the emission surface of the laser light. Note that, in the example illustrated in FIGS. 10A and 10B, the laser light passing portion 59 is constituted by the through hole, but a part or all of the laser light passing portion 59 may be constituted by a tangible object through which the laser light can pass.

In the above example (see particularly FIGS. 9B and 10 B), when the MEMS electric circuit 52 is turned on, the first MEMS electrode 53 and the second MEMS electrode 54 are charged to opposite polarities, but the first MEMS electrode 53 and the second MEMS electrode 54 may be charged to the same polarity.

That is, by turning on the MEMS electric circuit 52, both the first MEMS electrode 53 and the second MEMS electrode 54 may be positively charged or negatively charged. In such a case, electrostatic force (particularly repulsive force) acts on the first MEMS electrode 53 and the second MEMS electrode 54, the first MEMS electrode 53 is curved convexly toward the light-emitting unit 11 side, and stress is applied to the light-emitting unit 11 (particularly the active layer 24).

### Third Embodiment

In the present embodiment, elements same as or corresponding to those in the first and second embodiments described above will be denoted by the same reference signs, and detailed descriptions thereof will be omitted.

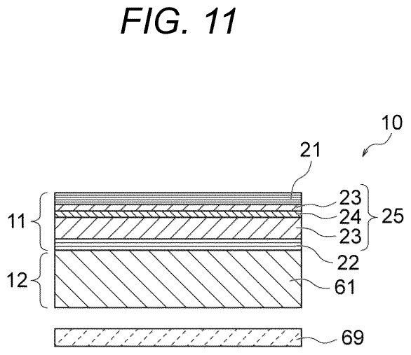

FIG. 11 is a cross-sectional view illustrating a schematic configuration of an example of a semiconductor light-emitting element 10 of a third embodiment.

The semiconductor light-emitting element 10 illustrated in FIG. 11 has a configuration similar to that of the semiconductor light-emitting element 10 illustrated in FIG. 1A described above, but the stress application unit 12 includes a thermal deformation portion 61.

The thermal deformation portion 61 is formed by a material having a higher thermal expansion coefficient than the semiconductor layer 23 and the active layer 24, and has a higher thermal expansion rate than the semiconductor layer 23 and the active layer 24. For example, in a case where the semiconductor layer 23 is formed by GaN, an inorganic material such as GaAs, Al2O3, Ni, Au, or Cu, or an organic material such as a polyimide resin or an epoxy resin may be used as a material constituting the thermal deformation portion 61. By applying thermal energy to such a thermal deformation portion 61 (stress application unit 12), stress is applied to the light-emitting unit 11 (particularly, the active layer 24).

Note that such thermal energy may be actively applied to the thermal deformation portion 61 or may be passively applied to the thermal deformation portion 61. That is, thermal energy may be applied to the thermal deformation portion 61 by the dedicated heating device 69, or thermal energy generated in the light-emitting unit 11 due to oscillation of the laser light may be applied thereto.

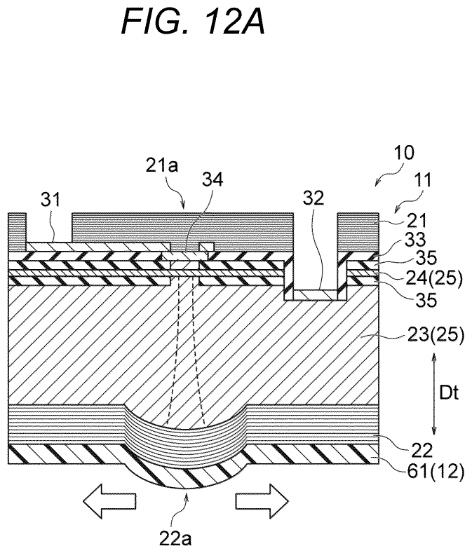

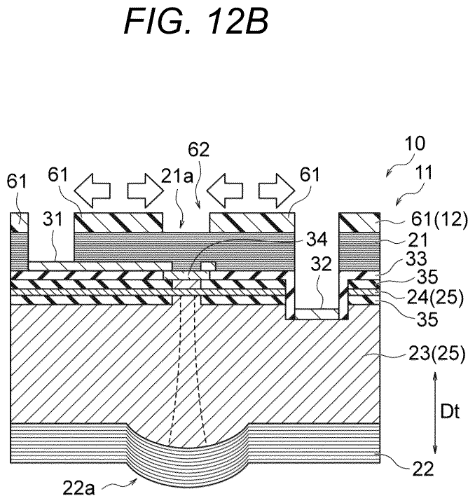

FIG. 12 a is a cross-sectional view illustrating an example in which the semiconductor light-emitting element 10 illustrated in FIG. 11 is applied to the VCSEL type light-emitting unit 11.

In the semiconductor light-emitting element 10 illustrated in FIG. 12A, the light-emitting unit 11 has the same structure as the light-emitting unit 11 illustrated in FIG. 2A described above, and the stress application unit 12 is attached to the light-emitting unit 11 (particularly, the second DBR 22). That is, the thermal deformation portion 61 of the stress application unit 12 is installed on a surface (that is, a surface formed by the second DBR 22) opposite to the emission surface of the laser light formed by the first DBR 21.

Also in the present example, the light emission electric circuit 45 (not illustrated in FIG. 12A; see FIG. 4B) is connected to the p-type semiconductor layer electrode 31 and the n-type semiconductor layer electrode 32 of the light-emitting unit 11.

The thermal deformation portion 61 illustrated in FIG. 12A covers the entire second DBR 22, and the thermal deformation portion 61 is attached to the entire outer surface of the second DBR 22. Therefore, in a case where the thermal deformation portion 61 expands according to applied thermal energy, outward stress (expansion force) is applied to the light-emitting unit 11 (particularly, the second DBR 22, the semiconductor layer 23, and the active layer 24).

FIG. 12B is a cross-sectional view illustrating another example in which the semiconductor light-emitting element 10 illustrated in FIG. 11 is applied to the VCSEL type light-emitting unit 11.

In the semiconductor light-emitting element 10 illustrated in FIG. 12B, the light-emitting unit 11 has the same structure as the light-emitting unit 11 illustrated in FIG. 2A described above, and the stress application unit 12 is attached to the light-emitting unit 11 (particularly, the first DBR 21). That is, the thermal deformation portion 61 of the stress application unit 12 is installed on the emission surface of the laser light (that is, the surface configured by the first DBR 21).

Also in the present example, the light emission electric circuit 45 (not illustrated in FIG. 12B; see FIG. 4B) is connected to the p-type semiconductor layer electrode 31 and the n-type semiconductor layer electrode 32 of the light-emitting unit 11.

The thermal deformation portion 61 illustrated in FIG. 12B covers only a part of the first DBR 21, and the outer surface (the upper surface in FIG. 12B) of the first DBR 21 has portions to which the thermal deformation portion 61 is attached and a portion to which the thermal deformation portion 61 is not attached, the portion being located between the portions to which the thermal deformation portion 61 is attached.

In particular, the thermal deformation portion 61 of the present example has a through hole constituting the laser light passing portion 62. The laser light passing portion 62 of the thermal deformation portion 61 is positioned to face the laser light transmission portion 21a of the first DBR 21 in the stacking direction Dt. That is, the laser light passing portion 62, the laser light transmission portion 21a, the through hole of the p-type semiconductor layer electrode 31, the transparent conductive film 34, the portions of the semiconductor layer 23 and the active layer 24 not covered with the high electric resistance region 35, and the concave reflection portion 22a are arranged on the same straight line extending in the stacking direction Dt, and constitute a waveguide of the laser light L.

As described above, since the thermal deformation portion 61 has the laser light passing portion 62, the laser light can be appropriately emitted from the light-emitting unit 11 even if the stress application unit 12 (thermal deformation portion 61) is provided on the emission surface of the laser light. Note that, in the example illustrated in FIG. 12B, the laser light passing portion 62 is configured by the through hole, but a part or the whole of the laser light passing portion 62 may be constituted by a tangible object through which the laser light can pass.

In a case where such a thermal deformation portion 61 expands according to given thermal energy, inward stress (compressive force) is applied to the light-emitting unit 11 (particularly, a portion of the active layer 24 on the waveguide through which a laser light that repeats reflection between the first DBR 21 and the second DBR 22 passes).

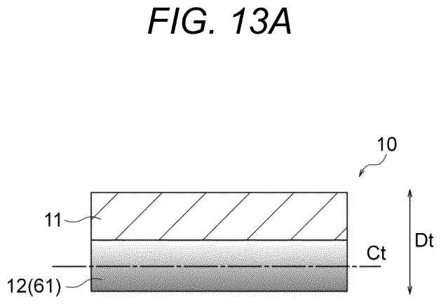

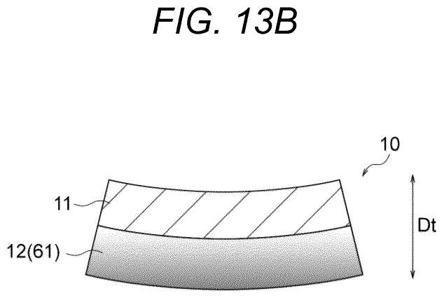

FIGS. 13A and 13B are cross-sectional views illustrating a schematic configuration of another example of the semiconductor light-emitting element 10 of the third embodiment.

The thermal expansion rate of the thermal deformation portion 61 included in the stress application unit 12 of the present example is asymmetric in the stacking direction Dt with reference to the center (thickness center Ct) of the thermal deformation portion 61 in the stacking direction Dt.

For example, in a case where the thermal expansion rate of the thermal deformation portion 61 is determined according to the carbon concentration of the thermal deformation portion 61, the thermal expansion rate of the thermal deformation portion 61 is asymmetric in the stacking direction Dt by making the carbon concentration of the thermal deformation portion 61 in the stacking direction Dt asymmetric with respect to the thickness center Ct.

Note that, in FIGS. 13A and 13B, the filling density of the stress application unit 12 (thermal deformation portion 61) changes in the stacking direction Dt, and a portion where the filling density is lower (a portion close to white) has a lower carbon concentration, and a portion where the filling density is higher (a portion close to black) has a higher carbon concentration.

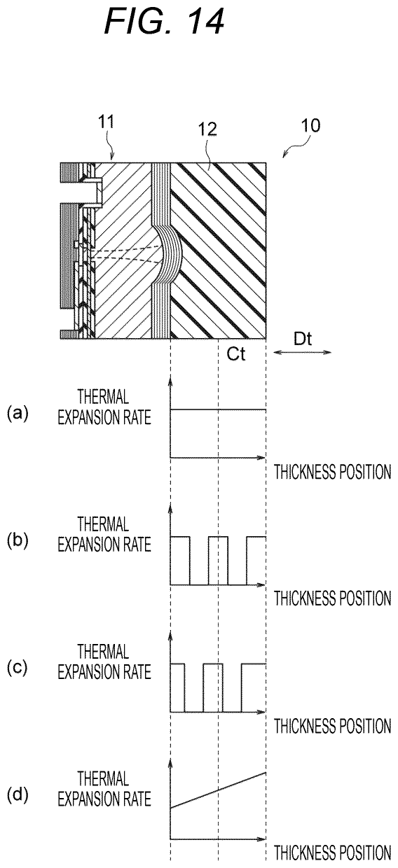

FIG. 14 is a view illustrating an example of a relationship between the thickness position in the stacking direction Dt of the stress application unit 12 and the thermal expansion rate.

The stress application unit 12 of the example illustrated in (a) of FIG. 14 has a constant thermal expansion rate regardless of the thickness position in the stacking direction Dt, and has a thermal expansion rate symmetrical with reference to the thickness center Ct in the stacking direction Dt. Furthermore, in the stress application unit 12 of the example illustrated in (b) of FIG. 14, a portion exhibiting a relatively large thermal expansion rate and a portion exhibiting a relatively small thermal expansion rate are alternately repeated in the stacking direction Dt, and have a thermal expansion rate symmetrical with reference to the thickness center Ct in the stacking direction Dt.

On the other hand, in the stress application unit 12 of the example illustrated in (c) of FIG. 14, a portion exhibiting a relatively large thermal expansion rate and a portion exhibiting a relatively small thermal expansion rate are alternately repeated in the stacking direction Dt, and have a thermal expansion rate asymmetric with reference to the thickness center Ct in the stacking direction Dt. Furthermore, the stress application unit 12 in the example illustrated in (d) of FIG. 14 has a thermal expansion rate that changes proportionally to the stacking direction Dt, and has a thermal expansion rate that is asymmetric with respect to the stacking direction Dt with reference to the thickness center Ct.

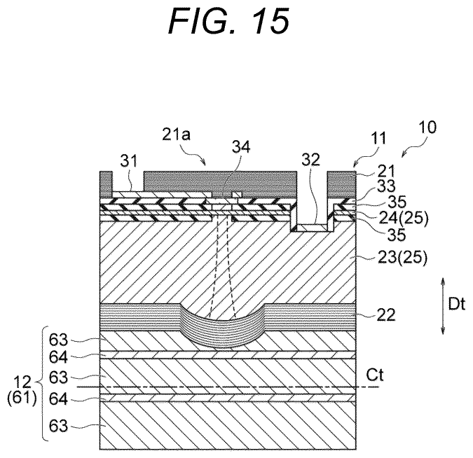

FIG. 15 is a cross-sectional view illustrating an example in which the semiconductor light-emitting element 10 illustrated in FIG. 13A is applied to the VCSEL type light-emitting unit 11.

In the semiconductor light-emitting element 10 illustrated in FIG. 15, the light-emitting unit 11 has the same structure as the light-emitting unit 11 illustrated in FIG. 2A described above, and the stress application unit 12 is attached to the light-emitting unit 11 (particularly, the second DBR 22). That is, the thermal deformation portion 61 of the stress application unit 12 is installed on a surface (that is, a surface formed by the second DBR 22) opposite to the emission surface of the laser light formed by the first DBR 21.

The thermal deformation portion 61 of the stress application unit 12 of the present example has a multilayer film structure including an organic layer 63 and an inorganic layer 64 having different thermal expansion rates, and the organic layer 63 and the inorganic layer 64 are alternately and repeatedly arranged in the stacking direction Dt.

In particular, the thermal expansion rate of the thermal deformation portion 61 of the present example is asymmetric in the stacking direction Dt with reference to the center (thickness center Ct) of the thermal deformation portion 61 in the stacking direction Dt (see (c) of FIG. 14). In the example illustrated in FIG. 15, although the central organic layer 63 is provided at a position corresponding to the thickness center Ct, by shifting the center of the central organic layer 63 in the stacking direction Dt from the thickness center Ct, asymmetry of the thermal expansion rate of the thermal deformation portion 61 in the stacking direction Dt is achieved.

As described above, by making the film thickness distribution of the thermal deformation portion 61 having the multilayer film structure with respect to the stacking direction Dt asymmetric with reference to the thickness center Ct, asymmetry of the thermal expansion rate of the thermal deformation portion 61 with respect to the stacking direction Dt can be achieved.

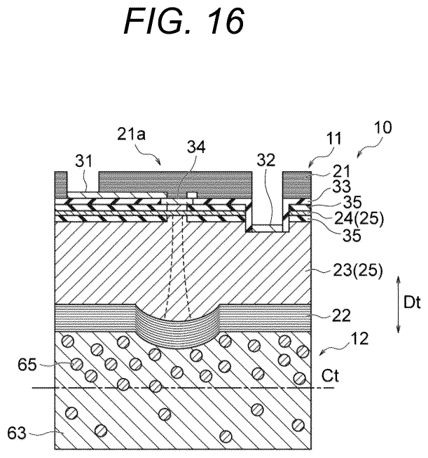

FIG. 16 is a cross-sectional view illustrating another example in which the semiconductor light-emitting element 10 illustrated in FIG. 13A is applied to the VCSEL type light-emitting unit 11.

In the semiconductor light-emitting element 10 illustrated in FIG. 16, the light-emitting unit 11 has the same structure as the light-emitting unit 11 illustrated in FIG. 2A described above, and the stress application unit 12 is attached to the light-emitting unit 11 (particularly, the second DBR 22). That is, the thermal deformation portion 61 of the stress application unit 12 is installed on a surface (that is, a surface formed by the second DBR 22) opposite to the emission surface of the laser light formed by the first DBR 21.

The thermal deformation portion 61 of the stress application unit 12 in the present example includes the organic layer 63 and the carbon 65 dispersed in the organic layer 63, and in particular, the carbon atom concentration affecting the thermal expansion rate of the thermal deformation portion 61 is non-uniform with respect to the stacking direction Dt and asymmetric with respect to the thickness center Ct (see (d) of FIG. 14).

Note that the thermal deformation portion 61 may include other substances (for example, inorganic particles) that affect the thermal expansion rate in addition to the carbon 65 or instead of the carbon 65, and the concentration of the other substances may be non-uniform with respect to the stacking direction Dt and may be asymmetric with respect to the thickness center Ct.

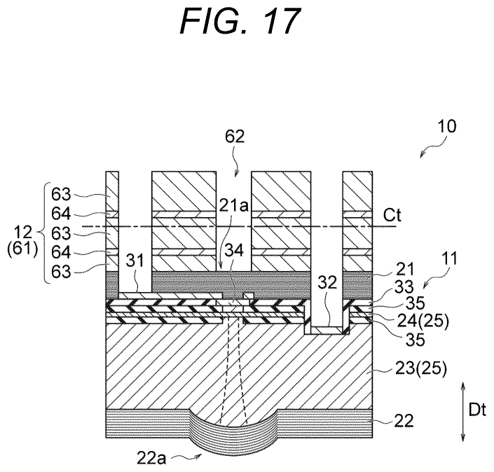

FIG. 17 is a cross-sectional view illustrating another example in which the semiconductor light-emitting element 10 illustrated in FIG. 13A is applied to the VCSEL type light-emitting unit 11.

In the semiconductor light-emitting element 10 illustrated in FIG. 17, the light-emitting unit 11 has the same structure as the light-emitting unit 11 illustrated in FIG. 2A described above, and the stress application unit 12 is attached to the light-emitting unit 11 (particularly, the first DBR 21). That is, the thermal deformation portion 61 of the stress application unit 12 is installed on the emission surface of the laser light (that is, the surface configured by the first DBR 21).

The thermal deformation portion 61 of the stress application unit 12 of the present example has a multilayer film structure including the organic layer 63 and the inorganic layer 64 having different thermal expansion rates, similar to the example illustrated in FIG. 15 described above, and the organic layer 63 and the inorganic layer 64 are alternately and repeatedly arranged in the stacking direction Dt. In particular, the thermal expansion rate of the thermal deformation portion 61 of the present example is asymmetric in the stacking direction Dt with reference to the center (thickness center Ct) of the thermal deformation portion 61 in the stacking direction Dt.

As described above, also in the present example, by making the film thickness distribution of the thermal deformation portion 61 having the multilayer film structure with respect to the stacking direction Dt asymmetric with reference to the thickness center Ct, asymmetry of the thermal expansion rate of the thermal deformation portion 61 with respect to the stacking direction Dt can be achieved.

In particular, the thermal deformation portion 61 of the present example has a through hole constituting the laser light passing portion 62. The laser light passing portion 62 of the thermal deformation portion 61 is positioned to face the laser light transmission portion 21a of the first DBR 21 in the stacking direction Dt. That is, the laser light passing portion 62, the laser light transmission portion 21a, the through hole of the p-type semiconductor layer electrode 31, the transparent conductive film 34, the portions of the semiconductor layer 23 and the active layer 24 not covered with the high electric resistance region 35, and the concave reflection portion 22a are arranged on the same straight line extending in the stacking direction Dt, and constitute a waveguide of the laser light L.

As described above, since the thermal deformation portion 61 has the laser light passing portion 62, the laser light can be appropriately emitted from the light-emitting unit 11 even if the stress application unit 12 (thermal deformation portion 61) is provided on the emission surface of the laser light. Note that, in the example illustrated in FIG. 17, the laser light passing portion 62 is constituted by the through hole, but a part or all of the laser light passing portion 62 may be constituted by a tangible object through which the laser light can pass.

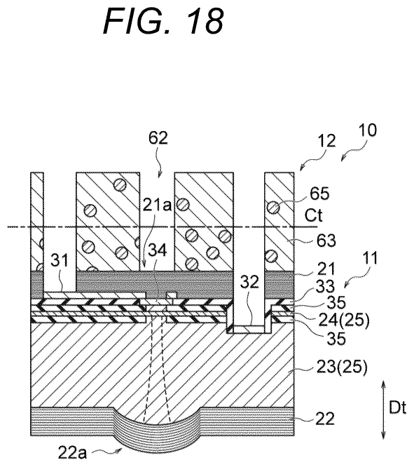

FIG. 18 is a cross-sectional view illustrating another example in which the semiconductor light-emitting element 10 illustrated in FIG. 13A is applied to the VCSEL type light-emitting unit 11.

In the semiconductor light-emitting element 10 illustrated in FIG. 18, the light-emitting unit 11 has the same structure as the light-emitting unit 11 illustrated in FIG. 2A described above, and the stress application unit 12 is attached to the light-emitting unit 11 (particularly, the first DBR 21). That is, the thermal deformation portion 61 of the stress application unit 12 is installed on the emission surface of the laser light (that is, the surface configured by the first DBR 21).

The thermal deformation portion 61 of the stress application unit 12 of the present example includes the organic layer 63 and the carbon 65 dispersed in the organic layer 63 similar to the example illustrated in FIG. 16 described above, and in particular, the carbon atom concentration affecting the thermal expansion rate of the thermal deformation portion 61 is non-uniform with respect to the stacking direction Dt and asymmetric with respect to the thickness center Ct.

Note that the thermal deformation portion 61 may include other substances (for example, inorganic particles) that affect the thermal expansion rate in addition to the carbon 65 or instead of the carbon 65, and the concentration of the other substances may be non-uniform with respect to the stacking direction Dt and may be asymmetric with respect to the thickness center Ct.

Furthermore, in the thermal deformation portion 61 of the present example, similar to the example illustrated in FIG. 17 described above, the through hole constituting the laser light passing portion 62 is provided so as to face the laser light transmission portion 21a of the first DBR 21 in the stacking direction Dt.

### Fourth Embodiment

In the present embodiment, elements same as or corresponding to those in the first to third embodiments described above will be denoted by the same reference signs, and detailed descriptions thereof will be omitted.

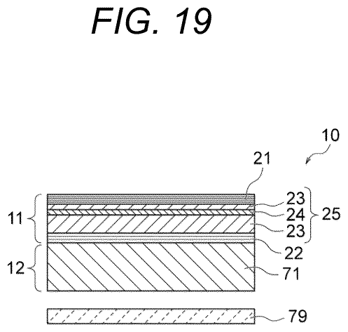

FIG. 19 is a cross-sectional view illustrating a schematic configuration of an example of a semiconductor light-emitting element 10 of a fourth embodiment.

The semiconductor light-emitting element 10 illustrated in FIG. 19 has a configuration similar to that of the semiconductor light-emitting element 10 illustrated in FIG. 1A described above, but the stress application unit 12 includes a light deformation portion 71. The light deformation portion 71 is deformed by being irradiated with light having a corresponding wavelength, and a stress corresponding to the deformation can be applied to the light-emitting unit 11.

Such light (light energy) may be actively applied to the light deformation portion 71 or passively applied to the light deformation portion 71. For example, light energy may be applied to the light deformation portion 71 by a dedicated light irradiation device 79.

The material that can constitute the light deformation portion 71 is not limited, and the type (wavelength or the like) of light that deforms the light deformation portion 71 is also not limited. As an example, the light deformation portion 71 may include a resin containing azobenzene exhibiting a photoisomerization reaction.

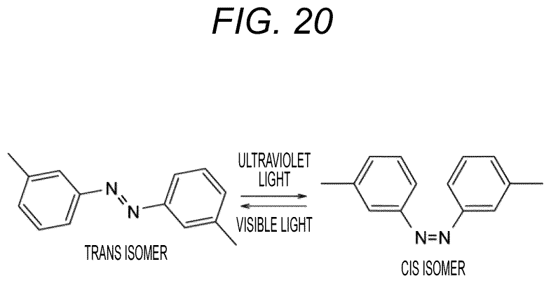

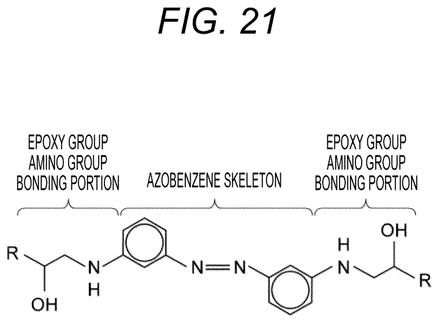

FIG. 20 is a view for describing a photoisomerization reaction of azobenzene. FIG. 21 is a chemical formula illustrating an example of a resin that can constitute the light deformation portion 71, and particularly illustrates an example of a resin having an azobenzene skeleton.

In general, as illustrated in FIG. 20, when irradiated with ultraviolet light, azobenzene is isomerized from a trans isomer to a cis isomer, and when irradiated with visible light (for example, blue light), azobenzene is isomerized from a cis isomer to a trans isomer, and is physically deformed by the isomerization.

In FIG. 21, “R” represents an epoxy resin main skeleton, “OH” represents a hydroxyl group, “N” represents a nitrogen atom, and “H” represents a hydrogen atom. That is, the resin illustrated in FIG. 21 contains an azobenzene skeleton, an epoxy resin main skeleton, an epoxy group, an amino group, and a bonding portion.

As described above, the light deformation portion 71 can be constituted by a resin in which an azobenzene skeleton is chemically bonded to a polyimide resin or an epoxy resin, and a stress can be applied to the light-emitting unit 11 (particularly, the active layer 24) by using deformation when light (for example, ultraviolet light) is irradiated.

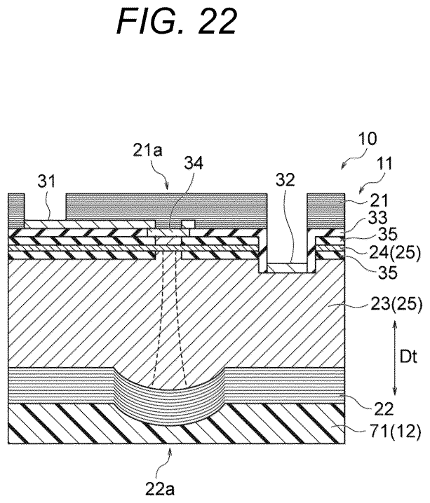

FIG. 22 is a cross-sectional view illustrating an example in which the semiconductor light-emitting element 10 illustrated in FIG. 19 is applied to the VCSEL type light-emitting unit 11.

In the semiconductor light-emitting element 10 illustrated in FIG. 22, the light-emitting unit 11 has the same structure as the light-emitting unit 11 illustrated in FIG. 2A described above, and the stress application unit 12 is attached to the light-emitting unit 11 (particularly, the second DBR 22). That is, the light deformation portion 71 of the stress application unit 12 is installed on a surface (that is, a surface constituted by the second DBR 22) opposite to the emission surface of the laser light constituted by the first DBR 21.

Also in the present example, the light emission electric circuit 45 (not illustrated in FIG. 22; see FIG. 4B) is connected to the p-type semiconductor layer electrode 31 and the n-type semiconductor layer electrode 32 of the light-emitting unit 11.

The light deformation portion 71 illustrated in FIG. 22 covers the entire second DBR 22, and the light deformation portion 71 is attached to the entire outer surface of the second DBR 22. By irradiating such a light deformation portion 71 with corresponding light (for example, ultraviolet rays), the light deformation portion 71 can be actively deformed, and stress can be actively applied to the light-emitting unit 11 (particularly, the active layer 24).

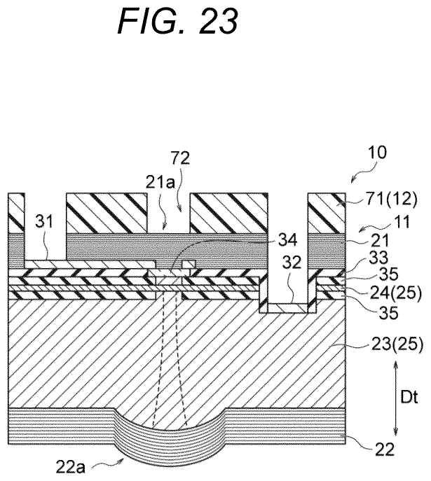

FIG. 23 is a cross-sectional view illustrating another example in which the semiconductor light-emitting element 10 illustrated in FIG. 19 is applied to the VCSEL type light-emitting unit 11.

In the semiconductor light-emitting element 10 illustrated in FIG. 23, the light-emitting unit 11 has the same structure as the light-emitting unit 11 illustrated in FIG. 2A described above, and the stress application unit 12 is attached to the light-emitting unit 11 (particularly, the first DBR 21). That is, the light deformation portion 71 of the stress application unit 12 is installed on the emission surface of the laser light (that is, the surface configured by the first DBR 21).

Also in the present example, the light emission electric circuit 45 (not illustrated in FIG. 23; see FIG. 4B) is connected to the p-type semiconductor layer electrode 31 and the n-type semiconductor layer electrode 32 of the light-emitting unit 11.

The light deformation portion 71 illustrated in FIG. 23 covers only a part of the first DBR 21, and the outer surface (the upper surface in FIG. 23) of the first DBR 21 has a portion to which the light deformation portion 71 is attached and a portion to which the light deformation portion 71 is not attached, the portion being located between the portions to which the light deformation portion 71 is attached.

In particular, the light deformation portion 71 of the present example has a through hole constituting the laser light passing portion 72. The laser light passing portion 72 of the light deformation portion 71 faces the laser light transmission portion 21a of the first DBR 21 in the stacking direction Dt. That is, the laser light passing portion 72, the laser light transmission portion 21a, the through hole of the p-type semiconductor layer electrode 31, the transparent conductive film 34, the portions of the semiconductor layer 23 and the active layer 24 not covered with the high electric resistance region 35, and the concave reflection portion 22a are arranged on the same straight line extending in the stacking direction Dt, and constitute a waveguide of the laser light L.

As described above, since the light deformation portion 71 has the laser light passing portion 72, the laser light can be appropriately emitted from the light-emitting unit 11 even if the stress application unit 12 (light deformation portion 71) is provided on the emission surface of the laser light. Note that, in the example illustrated in FIG. 23, the laser light passing portion 72 is constituted by the through hole, but a part or all of the laser light passing portion 72 may be constituted by a tangible object through which the laser light can pass.

By irradiating such a light deformation portion 71 with corresponding light (for example, ultraviolet rays), the light deformation portion 71 can be actively deformed, and stress can be actively applied to the light-emitting unit 11 (particularly, the active layer 24).

### Modification

In the above example, an example in which the second DBR 22 is mainly configured as a concave DBR has been described, but the first DBR 21 may be configured as a concave DB together with the second DBR 22 or instead of the second DBR 22. That is, the laser light transmission portion 21a of the first DBR 21 may include a concave reflection portion having a concave shape as viewed from the second DBR 22. A normal direction of at least a part of such a concave reflection portion (particularly, a reflection surface that is in contact with the semiconductor layer 23 and forms a boundary surface) of the laser light transmission portion 21a is directed to the second DBR 22 (for example, the concave reflection portion 22a).

It should be noted that the embodiments and variations disclosed in the present specification are illustrative only in all respects, and are not to be construed as limiting. The embodiments and variations described above may be omitted, replaced, or changed in various forms without departing from the scope and spirit of the appended claims. For example, the embodiments and variations described above may be combined in whole or in part, and other embodiments other than those described above may be combined with the embodiments or variations described above. Furthermore, the effects of the present disclosure described herein are merely examples, and other effects may be exerted.

A technical category embodying the technical idea described above is not limited. For example, the technical idea described above may be embodied by a computer program for causing a computer to execute one or a plurality of procedures (steps) included in the method of manufacturing or using the devices described above. Furthermore, the technical idea described above may be embodied by a computer-readable non-transitory recording medium in which such a computer program is recorded.

### Supplementary Note

The present disclosure technology can also have the following configurations.

### Configuration 1

A semiconductor light-emitting element including:
a light-emitting unit including a first distributed Bragg reflector and a second distributed Bragg reflector, and a semiconductor layer and an active layer located between the first distributed Bragg reflector and the second distributed Bragg reflector, and generates laser light; and
a stress application unit that applies stress to the light-emitting unit, in which
the second distributed Bragg reflector includes a concave reflection portion having a concave shape as viewed from the first distributed Bragg reflector.

### Configuration 2

The semiconductor light-emitting element according to configuration 1, in which
the light-emitting unit has a resonator length equal to or less than 50 μm.

### Configuration 3

The semiconductor light-emitting element according to configuration 1 or 2, in which
the light-emitting unit has a thickness equal to or less than 60 μm in a stacking direction in which the first distributed Bragg reflector, the active layer, the semiconductor layer, and the second distributed Bragg reflector are arranged.

### Configuration 4

The semiconductor light-emitting element according to any one of configurations 1 to 3, in which
the stress application unit is attached to the first distributed Bragg reflector.

### Configuration 5

The semiconductor light-emitting element according to any one of configurations 1 to 4, in which
the stress application unit is attached to the second distributed Bragg reflector.

### Configuration 6

The semiconductor light-emitting element according to any one of configurations 1 to 5, in which
the stress application unit includes a piezoelectric body, and applies a stress corresponding to a voltage applied to the piezoelectric body to the light-emitting unit.

### Configuration 7

The semiconductor light-emitting element according to any one of configurations 1 to 6, in which
the stress application unit is energized by an electric circuit independent of an electric circuit for energizing the light-emitting unit.

### Configuration 8

The semiconductor light-emitting element according to any one of configurations 1 to 7, in which
the light-emitting unit and the stress application unit are energized by a common electric circuit.

### Configuration 9

The semiconductor light-emitting element according to any one of configurations 1 to 8, in which
the light-emitting unit includes:
a first common electrode and a second common electrode to which a common electric circuit is connected; and
a connector electrically connected to the first common electrode and the second common electrode, and
the connector includes the stress application unit.

### Configuration 10

The semiconductor light-emitting element according to configuration 9, in which
the first distributed Bragg reflector includes a laser light transmission portion that allows transmission of the laser light emitted from the light-emitting unit, and
when viewed along an emission direction of the laser light from the light-emitting unit, the laser light transmission portion is located between the first common electrode and the second common electrode.

### Configuration 11

The semiconductor light-emitting element according to any one of configurations 1 to 10, in which
the stress application unit includes a MEMS structure.

### Configuration 12

The semiconductor light-emitting element according to configuration 11, in which
the MEMS structure includes
a first MEMS electrode and a second MEMS electrode, and
a stress application layer attached to the light-emitting unit and deformed according to a voltage applied via the first MEMS electrode and the second MEMS electrode, and
a stress according to deformation of the stress application layer is applied to the light-emitting unit.

### Configuration 13

The semiconductor light-emitting element according to configuration 12, in which
the first MEMS electrode and the second MEMS electrode face each other with an air gap interposed therebetween, and
the stress application layer is attached to the first MEMS electrode.

### Configuration 14

The semiconductor light-emitting element according to any one of configurations 1 to 13, in which
the stress application unit includes a thermal deformation portion having a larger thermal expansion rate than the semiconductor layer.

### Configuration 15

The semiconductor light-emitting element according to configuration 14, in which
a thermal expansion rate of the thermal deformation portion is asymmetric in a stacking direction with reference to a center of the thermal deformation portion in the stacking direction in which the first distributed Bragg reflector, the semiconductor layer, and the second distributed Bragg reflector are arranged.

### Configuration 16

The semiconductor light-emitting element according to any one of configurations 1 to 15, in which
the stress application unit includes a light deformation portion that deforms according to irradiated light.

### Configuration 17

The semiconductor light-emitting element according to configuration 16, in which
the light deformation portion includes a resin containing azobenzene.

### Configuration 18

The semiconductor light-emitting element according to configuration 17, in which
the resin is a polyimide resin or an epoxy resin.

### REFERENCE SIGNS LIST

10 Semiconductor light-emitting element
11 Light-emitting unit
12 Stress application unit
21 First DBR
21a Laser light transmission portion
22 Second DBR
22a Concave reflection portion
22b Flat reflecting portion
23 Semiconductor layer
24 Active layer
25 Stacked structure
31 p-type semiconductor layer electrode
32 n-type semiconductor layer electrode
33 Insulating layer
34 Transparent conductive film
35 High electric resistance region
41 Piezoelectric body
41a Laser light passing portion
45 Light emission electric circuit
45a Power supply
45b Electrode
45c Electrode
45d Switch
46 Stress application electric circuit
46a Power supply
46b Electrode
46c Electrode
46d Switch
47 Common electric circuit
47a Power supply
47b Electrode
47c Electrode
50 Connection layer
51 MEMS structure
52 MEMS electric circuit
53 First MEMS electrode
54 Second MEMS electrode
55 Air gap
56 Spacer
57 Mounting substrate
58 Support substrate
59 Laser light passing portion
61 Thermal deformation portion
62 Laser light passing portion
63 Organic layer
64 Inorganic layer
65 Carbon
69 Heating device
71 Light deformation portion
72 Laser light passing portion
79 Light irradiation device
Ct Thickness center
DL Diagonal line
Dt Stacking direction
L Laser light
T1 Stacking direction thickness
T2 Resonator length

1. A semiconductor light-emitting element comprising:
a light-emitting unit including a first distributed Bragg reflector and a second distributed Bragg reflector, and a semiconductor layer and an active layer located between the first distributed Bragg reflector and the second distributed Bragg reflector, and generates laser light; and
a stress application unit that applies stress to the light-emitting unit, wherein
the second distributed Bragg reflector includes a concave reflection portion having a concave shape as viewed from the first distributed Bragg reflector.

2. The semiconductor light-emitting element according to claim 1, wherein
the light-emitting unit has a resonator length equal to or less than 50 μm.

3. The semiconductor light-emitting element according to claim 1, wherein
the light-emitting unit has a thickness equal to or less than 60 μm in a stacking direction in which the first distributed Bragg reflector, the active layer, the semiconductor layer, and the second distributed Bragg reflector are arranged.

4. The semiconductor light-emitting element according to claim 1, wherein
the stress application unit is attached to the first distributed Bragg reflector.

5. The semiconductor light-emitting element according to claim 1, wherein
the stress application unit is attached to the second distributed Bragg reflector.

6. The semiconductor light-emitting element according to claim 1, wherein
the stress application unit includes a piezoelectric body, and applies a stress corresponding to a voltage applied to the piezoelectric body to the light-emitting unit.

7. The semiconductor light-emitting element according to claim 1, wherein
the stress application unit is energized by an electric circuit independent of an electric circuit for energizing the light-emitting unit.

8. The semiconductor light-emitting element according to claim 1, wherein
the light-emitting unit and the stress application unit are energized by a common electric circuit.

9. The semiconductor light-emitting element according to claim 1, wherein
the light-emitting unit includes:
a first common electrode and a second common electrode to which a common electric circuit is connected; and
a connector electrically connected to the first common electrode and the second common electrode, and
the connector includes the stress application unit.

10. The semiconductor light-emitting element according to claim 9, wherein
the first distributed Bragg reflector includes a laser light transmission portion that allows transmission of the laser light emitted from the light-emitting unit, and
when viewed along an emission direction of the laser light from the light-emitting unit, the laser light transmission portion is located between the first common electrode and the second common electrode.

11. The semiconductor light-emitting element according to claim 1, wherein
the stress application unit includes a MEMS structure.

12. The semiconductor light-emitting element according to claim 11, wherein
the MEMS structure includes
a first MEMS electrode and a second MEMS electrode, and
a stress application layer attached to the light-emitting unit and deformed according to a voltage applied via the first MEMS electrode and the second MEMS electrode, and
a stress according to deformation of the stress application layer is applied to the light-emitting unit.

13. The semiconductor light-emitting element according to claim 12, wherein
the first MEMS electrode and the second MEMS electrode face each other with an air gap interposed therebetween, and
the stress application layer is attached to the first MEMS electrode.

14. The semiconductor light-emitting element according to claim 1, wherein
the stress application unit includes a thermal deformation portion having a larger thermal expansion rate than the semiconductor layer.

15. The semiconductor light-emitting element according to claim 14, wherein
a thermal expansion rate of the thermal deformation portion is asymmetric in a stacking direction with reference to a center of the thermal deformation portion in the stacking direction in which the first distributed Bragg reflector, the semiconductor layer, and the second distributed Bragg reflector are arranged.

16. The semiconductor light-emitting element according to claim 1, wherein
the stress application unit includes a light deformation portion that deforms according to irradiated light.

17. The semiconductor light-emitting element according to claim 16, wherein
the light deformation portion includes a resin containing azobenzene.

18. The semiconductor light-emitting element according to claim 17, wherein
the resin is a polyimide resin or an epoxy resin.
